(19) United States
(12) Patent Application Publication
(10) Pub. No.: US 2026/0360461 A1
(43) Pub. Date: Nov. 12, 2026

(54) Storage Array Read/Write Circuit and Read/Write Method

(71) Applicant: ZHEJIANG HIKSTOR TECHNOLOGY CO., LTD., Hangzhou, Zhejiang (CN)

(72) Inventors: Dandan LI, Hangzhou, Zhejiang (CN); Ao SHEN, Hangzhou, Zhejiang (CN); Pengqi LU, Hangzhou,Zhejiang (CN)

(21) Appl. No.: 19/153,589

(22) PCT Filed: Nov. 27, 2023
(86) PCT No.: PCT/CN2023/134473

§ 371 Date: Aug. 4, 2025

(30) Foreign Application Priority Data
Feb. 7, 2023 (CN) 202310105178.1

(51) Int. Cl. G11C 29/00

(52) U.S. Cl. CPC G11C 29/785; G11C 29/76

(57) ABSTRACT

The present disclosure provides a storage array read/write circuit and read/write method. The storage array read/write circuit includes: a storage array, including a plurality of array rows and a plurality of redundant rows, wherein the array rows are used for conventional read/write data, and the redundant rows are used for replacing array rows having a defective point; an array row line resistance compensation circuit, configured to provide different line resistance compensation for near-end array row bit cells and far-end array row bit cells in a case that the array row bit cells perform a read/write operation; and a redundant row line resistance compensation circuit, configured to provide different line resistance compensation for near-end redundant row bit cells and far-end redundant row bit cells in a case that the redundant row bit cells perform a read/write operation,

### CROSS-REFERENCE TO RELATED APPLICATION

The present disclosure claims priority to Chinese Patent Application No. 2023101051781, filed to the China National Intellectual Property Administration on Feb. 7, 2023 and entitled “Storage Array Read/Write Circuit and Read/Write Method”, which is incorporated herein by reference in its entirety.

### TECHNICAL FIELD

The present disclosure relates to the field of memory technologies, and in particular, to a storage array read/write circuit and read/write method.

### BACKGROUND

In the integrated circuit manufacturing process, some defective points may occur. For example, defective points in a storage array can cause the corresponding bit cell to fail and become unable to store data. Therefore, a redundant repair circuit is designed to replace the rows or columns containing defective points in the original array, thereby improving the yield of the array and the chip manufacturing process.

For a column in the storage array, due to the bit line/source line (BL/SL) lengths differ between near-end and far-end bit cells, the resistance caused by the wiring varies, leading to different voltage drops across the line resistances. In a case that the same write voltage is provided externally, the voltage reaching the bit device varies, which can result in differences in device lifespan. Therefore, an additional line resistance compensation design is implemented to address the differences between the near-end and far-end of the array, with larger compensation resistance at the near-end and smaller or no compensation at the far-end.

However, existing designs only consider line resistance compensation for array bit cells. After replacing an array row having a defective point with a redundant row, the line resistance compensation is still provided based on the address of the replaced row. This may result in scenarios where a near-end redundant row replaces a far-end array row, or a far-end redundant row replaces a near-end array row, leading to the mismatch in line resistance compensation. Consequently, this can affect the device lifespan and result in write failures.

### SUMMARY

In view of this, some embodiments of the present disclosure provide a storage array read/write circuit and read/write method.

According to a first aspect, some embodiments of the present disclosure provide a storage array read/write circuit, the storage array read/write circuit includes:
a storage array, including a plurality of array rows and a plurality of redundant rows, wherein the array rows are used for conventional read/write data, and the redundant rows are used for replacing array rows having a defective point;
an array row line resistance compensation circuit, connected to bit lines and source lines of each column of the storage array, and configured to provide different line resistance compensation for near-end array row bit cells and far-end array row bit cells in a case that the array row bit cells perform a read/write operation, such that a line resistance of the near-end array row bit cells and a line resistance of the far-end array row bit cells is equal; and
a redundant row line resistance compensation circuit, connected to bit lines and source lines of each column of the storage array, and configured to provide different line resistance compensation for near-end redundant row bit cells and far-end redundant row bit cells in a case that the redundant row bit cells perform a read/write operation, such that a line resistance of the near-end redundant row bit cells and a line resistance of the far-end redundant row bit cells is equal.

In some embodiments of the present disclosure, the storage array read/write circuit further includes:
a determination circuit, configured to determine whether a control signal of a redundant row is “1”, and in a case that a control signal of a redundant row is “1”, select a corresponding redundant row, and enable the redundant row line resistance compensation circuit; and
in a case that all the control signals of the redundant rows are “0”, select an array row to be read and written, and enable the array row line resistance compensation circuit.

In some embodiments of the present disclosure, the storage array read/write circuit further includes:
a failure address comparison circuit, configured to compare an address of an array row to be read and written with an address of a known array row having a defective point, and if the comparison between the two is successful, set a control signal of a redundant row used for replacement to be “1”.

In some embodiments of the present disclosure, the array rows are divided into N groups, each of which has 2*2ⁿ rows, the redundant rows are divided into N groups, each of which has m rows, and m redundant rows are inserted between every 2*2ⁿ array rows.

In some embodiments of the present disclosure, the redundant row line resistance compensation circuit includes:
a first compensation sub-circuit connected to the bit line, including N first PMOSs, N first NMOSs and N compensation resistors, wherein
drain terminals of the N first PMOSs are connected together and then connected to a bit line voltage input terminal, source terminals of the N first PMOSs are connected to drain terminals of the N first NMOSs in one-to-one correspondence, source terminals of the N first NMOSs are connected together and then grounded, and the N compensation resistors are connected in series between the bit lines and the drain terminals of the N first NMOSs;
the N first PMOSs are configured to respectively provide compensation paths for different redundant rows between the bit line voltage input terminal and the bit line;
the N first NMOSs are configured to respectively provide compensation paths for different redundant rows between the bit line and the ground terminal;
and
a second compensation sub-circuit connected to the source line, including N second PMOSs, N second NMOSs and N compensation resistors, wherein
drain terminals of the N second PMOSs are connected together and then connected to a source line voltage input terminal, source terminals of the N second PMOSs are connected to drain terminals of the N second NMOSs in one-to-one correspondence, source terminals of the N second NMOSs are connected together and then grounded, and the N compensation resistors are connected in series between the source line and the drain terminals of the N second NMOSs;
the N second PMOSs are configured to respectively provide compensation paths for different redundant rows between the source line voltage input terminal and the source line; and
the N second NMOSs are configured to respectively provide compensation paths for different redundant rows between the source line and the ground terminal.

In some embodiments of the present disclosure, gate terminals of the N first PMOSs access first control signals corresponding to N groups of redundant rows;
gate terminals of the N first NMOSs access second control signals corresponding to N groups of redundant rows;
gate terminals of the N second PMOSs access third control signals corresponding to N groups of redundant rows; and
gate terminals of the N second NMOSs access fourth control signals corresponding to N groups of redundant rows.

In some embodiments of the present disclosure, the value of a compensation resistor connected to the bit line and drain terminals of the first NMOSs is Rw;
a value of a compensation resistor connected between the drain terminals of the first NMOSs is 2Rw;
a value of a compensation resistor connected to the source line and the drain terminals of the second NMOSs is Rw;
a value of a compensation resistor connected between the drain terminals of the second NMOSs is 2Rw;
wherein the value of Rw is equal to a parasitic line resistance of the bit line/source line wiring with the length of the 2ⁿ array rows.

In some embodiments of the present disclosure, the storage array read/write circuit further includes:
a data read-out circuit, which is connected to the bit line voltage input terminal and reads out data of array row bit cells or redundant row bit cells during a read operation.

According to a second aspect, some embodiments of the present disclosure provide a storage array read/write method, the storage array read/write method includes:
an address of an array row to be read and written is compared with an address of a known array row having a defective point, and if the comparison between the two is successful, a control signal of a redundant row used for replacement is set to be “1”; and
it is determined whether a control signal of a redundant row is “1”, and in a case that a control signal of a redundant row is “1”, a corresponding redundant row is selected, and a redundant row resistance compensation circuit is enabled; in a case that all control signals of the redundant rows are “0”, an array row to be read and written is selected, and an array row line resistance compensation circuit is enabled.

In some embodiments of the present disclosure, the address of the known array row having a defective point is stored in a redundant address register.

### BRIEF DESCRIPTION OF THE DRAWINGS

FIG. 1 is a schematic structural diagram of a storage array read/write circuit according to some embodiments of the present disclosure;

FIG. 2 is a schematic structural diagram of a redundant row recovery scheme according to some embodiments of the present disclosure;

FIG. 3 is a schematic structural diagram of a redundant row line resistance compensation circuit according to embodiments of the present disclosure;

FIG. 4 is a schematic structural diagram of a compensation path of a redundant row line resistance compensation circuit according to embodiments of the present disclosure; and

FIG. 5 is a schematic flowchart of a storage array read/write method according to some embodiments of the present disclosure.

The figures above include the following reference signs:
101. storage array; 102. array row line resistance compensation circuit; 103. redundant row line resistance compensation circuit; 104. determination circuit; 105. failure address comparison circuit; 10. conventional array rows in an array; 11. redundant row inserted into an array; 301. source line voltage (VSL) input at two ends of a bit cell structure; 302. bit line voltage (VBL) input at two ends of a bit cell structure; 303, 304, 305, 306. gate terminal control signals; 307, line resistance compensation unit resistance Rw; 308. parasitic line resistance Rc of the bit line/source line wiring with the length of the 2ⁿ array rows; 309. MTJ; 310. CMOS; 311. SW switch; 312. read control switch Clamp; 313. sense amplifier (SA); 41, 42. compensation path.

### DETAILED DESCRIPTION OF THE EMBODIMENTS

To make the objects, technical solutions and advantages of embodiments of the present disclosure clearer, hereinafter, the technical solutions in the embodiments of the present disclosure will be described clearly and thoroughly in conjunction with the accompanying drawings in the embodiments of the present disclosure. Obviously, the embodiments as described are only some of embodiments of the present disclosure, and are not all the embodiments. On the basis of the embodiments in the present disclosure, all other embodiments obtained by a person of ordinary skill in the art without any inventive effort shall all fall within the scope of protection of the present disclosure.

It should be noted that the terms “first”, “second” etc., in the description, claims, and accompanying drawings of the present disclosure are used to distinguish similar objects, and are not necessarily used to describe a specific sequence or order. It should be understood that the data so used may be interchanged where appropriate, so that embodiments of the present disclosure described herein can be implemented in sequences other than those illustrated or described herein. In addition, the terms “include” and “have” and any variations thereof are intended to cover a non-exclusive inclusion, for example, a process, method, system, product or device that includes a series of steps or units is not necessarily limited to those steps or units that are clearly listed, but may include other steps or units that are not clearly listed or inherent to such process, method, product or device.

In the present disclosure, the orientation or position relationships indicated by the terms such as “upper”, “lower”, “left”, “right”, “front”, “rear”, “top”, “bottom”, “inner”, “outer”, “middle”, “vertical”, “horizontal”, “lateral”, and “longitudinal” are the orientation or position relationships based on those as shown in the accompanying drawings. These terms are used primarily to better describe the present disclosure and embodiments thereof, and are not intended to limit that the device, element, or component referred to must have a specific orientation, or be constructed and operated in a specific orientation.

Furthermore, some of the above terms may be used to indicate an orientation or position relationship, and may also be used to indicate other meanings, for example, the term “on” may also be used to indicate a certain dependence relationship or connection relationship in some cases. For a person of ordinary skill in the art, specific meanings of the terms above in the present disclosure could be understood according to specific situations.

In addition, the terms “mount”, “configure”, “provide”, “connecting”, “connect to”, and “sleeve” should be understood broadly. For example, it may be a fixed connection, a detachable connection, or an integral configuration; it may be a mechanical connection, or an electrical connection; it may be direct connection, or indirect connection by means of an intermediate medium, or internal communication between two devices, elements, or components. For a person of ordinary skill in the art, specific meanings of the terms above in the present disclosure could be understood according to specific situations.

Hereinafter, some embodiments of the present disclosure will be described in detail in combination with the accompanying drawings. The following embodiments and features in the embodiments may be combined with one another without conflicts.

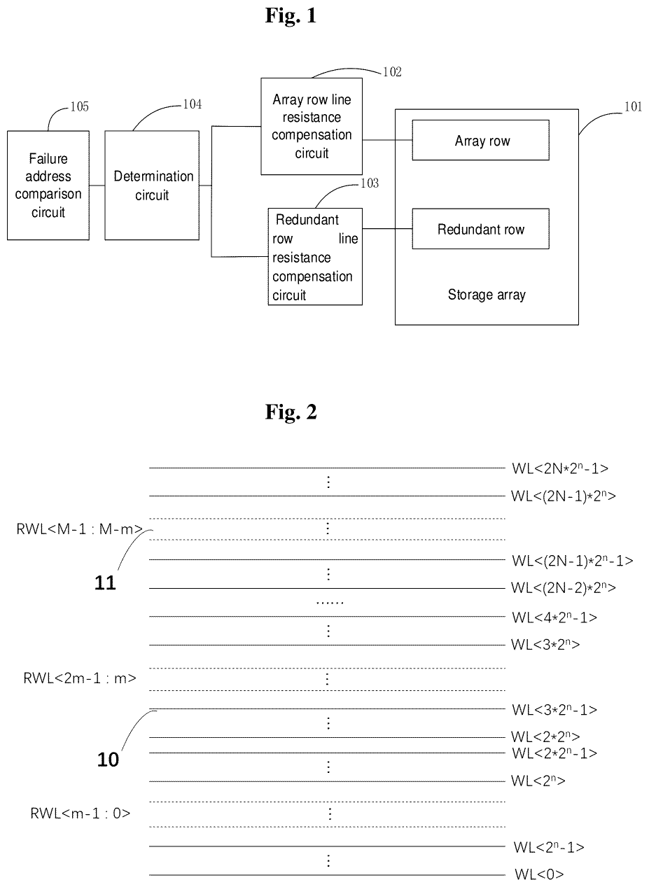

An embodiment of the present disclosure provides a storage array read/write circuit. FIG. 1 shows a structural block diagram of the circuit. As shown in FIG. 1, the circuit includes:
a storage array 101, including a plurality of array rows and a plurality of redundant rows, wherein the array rows are used for conventional read/write data, and the redundant rows are used for replacing array rows having a defective point;
an array row line resistance compensation circuit 102, connected to bit lines and source lines of each column of the storage array, and configured to provide different resistance compensation for near-end array row bit cells and far-end array row bit cells in a case that the array row bit cells perform a read/write operation, such that line resistance of the near-end array row bit cells and the far-end array row bit cells is equal; and
a redundant row line resistance compensation circuit 103, connected to bit lines and source lines of each column of the storage array, and configured to provide different line resistance compensation for near-end redundant row bit cells and far-end redundant row bit cells in a case that the redundant row bit cells perform a read/write operation, such that line resistance of the near-end redundant row bit cells and the far-end redundant row bit cells is equal.

In some implementations, referring to FIG. 1, the circuit includes a determination circuit 104 and a failure address comparison circuit 105.

The determination circuit 104 is configured to determine whether a control signal of a redundant row is “1”, and in a case that a control signal of a redundant row is “1”, the corresponding redundant row is selected, and the redundant row line resistance compensation circuit 103 is enabled; and
in a case that all the control signals of the redundant rows are “0”, the array row to be read or written is selected, and the array row line resistance compensation circuit 102 is enabled.

The failure address comparison circuit 105 is configured to compare an address of an array row to be read and written with an address of a known array row having a defective point, and if the comparison between the two is successful, a control signal of a redundant row used for replacement is set to be “1”.

Specifically, in a test process of a memory chip, if an array row having a defective point is detected, redundant row repair is performed, that is, the array row having a defective point is replaced with a redundant row, that is, the correlation between the redundant row and the replaced row is configured during the test. Furthermore, during the redundant row repair, the address of the replaced row is written into a redundant address register (or referred to as redundancy fuses).

During a read/write operation, the input signals of the failure address comparison circuit 105 are the address of an array row to be read/written and the address of the replaced row stored in the redundant address register, and if the comparison between the two is successful, it indicates that the array row to be read/written is an array row having a defective point, and needs to be replaced by a redundant row, and a control signal of the corresponding redundant row is set to be 1. If the comparison between the addresses is unsuccessful, it indicates that the array row to be read/written is a normal array row, and no repair and replacement is required.

Assuming that there are M redundant rows in the array, then there are control signals Frwle<0> to Frwle<M-1> of the M redundant rows, and it can be understood that M control signals Frwle<0> to Frwle<M-1> may simply written as Frwle<M-1:0>. The determination circuit 104 makes a determination according to whether the control signals Frwle<M-1:0> of the redundant rows are high or low, as long as the value of any one of the control signals Frwle<M-1:0> of the M redundant rows is 1 (in one read/write operation, only one value can be taken as 1), then the row to be read and written needs to be replaced by the redundant row, and the redundant row line resistance compensation circuit 103 is enabled; and if all Frwle<M-1:0> are 0, the row to be read and written is a normal array row, and the array row compensation circuit 102 is enabled.

According to the storage array read/write circuit provided in the embodiments of the present disclosure, in a case that it is determined that an array row to be read or written is an array row having a defective point, the control signal of the corresponding redundant row is set to be 1. A determination circuit is added, and if the control signal of the redundant row is 1, the redundant row line resistance compensation circuit is enabled, and the corresponding line resistance compensation is performed according to the position of the redundant row in the array, achieving the same effect as the array compensation; and if the control signals of all redundant rows are 0, the existing array compensation scheme is adopted. The embodiments of the present disclosure can effectively avoid the mismatch in line resistance compensation caused by differences in near-end and far-end positions between the redundant row and the replaced row in the existing array compensation schemes, thereby addressing issues such as reduced device lifespan or write failures.

In some embodiments, FIG. 2 shows a redundant row repair scheme of array rows and redundant rows. As shown in FIG. 2, reference sign 10 denotes conventional array rows in the array, the array rows are referred to as word lines (WL) for simplicity, the dotted portions denoted by reference sign 11 are the inserted redundant rows in the array, and the redundant rows are referred to as word lines (RWL). The array rows are divided into N groups, each of which has 2*2ⁿ rows, and there are a total of N*2*2ⁿ rows, where N=1, 2, 3, . . . ; and the redundant rows are divided into N groups, each of which has m rows, and there are a total of N*m redundant rows, written as M=N*m, and m redundant rows are inserted between every 2*2ⁿ array rows.

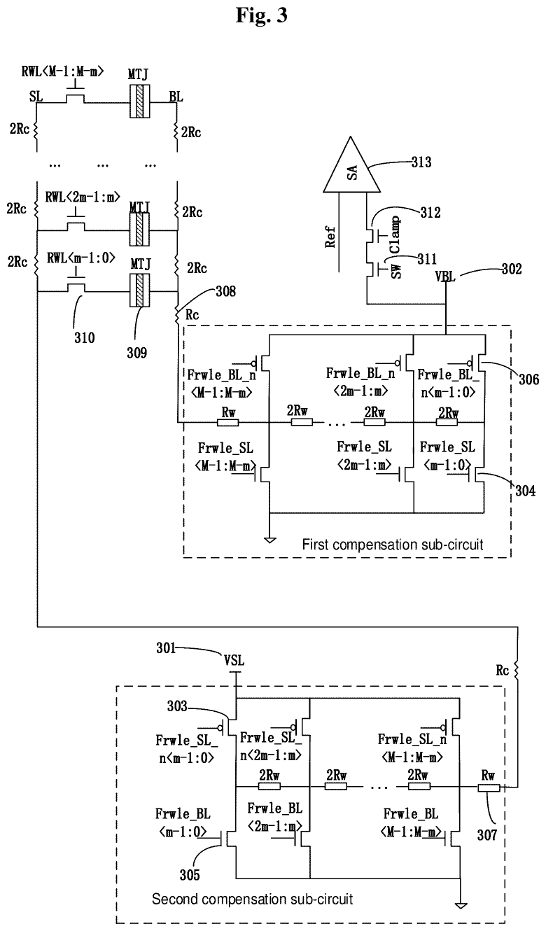

In some embodiments, FIG. 3 shows a schematic structural diagram of a redundant row line resistance compensation circuit provided in the embodiments of the present disclosure. The line resistance compensation is performed on write-0, write-1 and read paths, and the magnitude of the line resistance compensation is controlled by four control signals Frwle_SL_n<M-1:0>, Frwle_SL<M-1:0>, Frwle_BL_n<M-1:0> and Frwle_BL<M-1:0>, which will be described in detail below.

It is first assumed that (1) there are a total of N*2*2ⁿ array rows and are divided into N groups, each of which has 2*2ⁿ rows; there are a total of M(M=N*m) redundant rows and are divided into N groups, each of which has m rows; and m redundant rows are inserted between every 2*2ⁿ array rows; and (2) a parasitic resistance of a bit line/source line (BL/SL) wiring with a length of 2ⁿ array rows is Rc.

As shown in FIG. 3, the redundant row line resistance compensation circuit includes:
a first compensation sub-circuit which is connected to the BL, and includes N first PMOSs, N first NMOSs and N compensation resistors, wherein
drain terminals of the N first PMOSs are connected together and then connected to a bit line voltage input terminal, source terminals of the N first PMOSs are connected to drain terminals of the N first NMOSs in one-to-one correspondence, source terminals of the N first NMOSs are connected together and then grounded, and N compensation resistors are connected in series between the bit line and the drain terminals of the N first NMOSs;
the N first PMOSs are configured to respectively provide compensation paths for different redundant rows between the bit line voltage input terminal and the bit line;
the N first NMOSs are configured to respectively provide compensation paths for different redundant rows between the bit line and the ground terminal;
and
a second compensation sub-circuit which is connected to the SL, and includes N second PMOSs, N second NMOSs and N compensation resistances, wherein
drain terminals of the N second PMOSs are connected together and then connected to a source line voltage input terminal, source terminals of the N second PMOSs are connected to drain terminals of N second NMOSs in one-to-one correspondence, source terminals of the N second NMOSs are connected together and then grounded, and N compensation resistors are connected in series between the source line and the drain terminals of the N second NMOSs;
the N second PMOSs are configured to respectively provide compensation paths for different redundant rows between the source line voltage input terminal and the source line; and
the N second NMOSs are configured to respectively provide compensation paths for different redundant rows between the source line and the ground terminal.

Further, the gate terminals of the N first PMOSs access the first control signals Frwle_BL_n<m-1:0>, Frwle_BL_n<2m-1:m>, . . . , Frwle_BL_n<M-1:M-m> corresponding to the N groups of redundant rows;
the gate terminals of the N first NMOSs access the second control signals Frwle_SL<m-1:0>, Frwle_SL<2m-1:m>, . . . , Frwle_SL<M-1:M-m> corresponding to the N groups of redundant rows; the gate terminals of the N second PMOSs access the third control signals Frwle_SL_n<m-1:0>, Frwle_SL_n<2m-1:m>, . . . , Frwle_SL_n<M-1:M-m> corresponding to the N groups of redundant rows; and
the gate terminals of the N second NMOSs access the fourth control signals Frwle_BL<m-1:0>, Frwle_BL<2m-1:m>, . . . , Frwle_BL<M-1:M-m> corresponding to the N groups of redundant rows.

In some implementations, the value of a compensation resistor connected between the bit line and the drain terminals of the first NMOSs is Rw; the value of a compensation resistor connected between the drain terminals of the first NMOSs is 2Rw; the value of a compensation resistor connected between the source line and the drain terminals of the second NMOSs is Rw; the value of a compensation resistor connected between the drain terminals of the second NMOSs is 2Rw; wherein the value Rw is equal to the parasitic line resistance of the bit line/source line wiring with the length of 2ⁿ array rows.

As shown in FIGS. 3, 301 and 302 respectively refer to a source line voltage (VSL) and a bit line voltage (VSL) which are input at two ends of a bit cell structure; 303, 304, 305 and 306 refer to gate terminal control signals, the number of which is N; wherein Frwle_SL_n< > is inverted to Frwle_SL< >, for example, Frwle_SL_n<m-1:0> is inverted to Frwle_SL<m-1:0>, and the remaining signals are similar; and signal Frwle BL_n< > is inverted to Frwle_BL< >, for example, signal Frwle_BL_n<m-1:0>is inverted to Frwle_BL<m-1:0>, and the remaining signals are similar. 307 refers to a line resistance compensation unit resistance Rw, 308 refers to a parasitic line resistance Rc of the bit line/source line wiring with the length of the 2ⁿ array rows, 309 and 301 form a bit cell structure, 309 refers to an MTJ, and 310 refers to a CMOS.

In some implementations, the read/write circuit further includes: a data read-out circuit which is connected to a bit line voltage input terminal and reads out data of the array row bit cells or redundant row bit cells during a read operation. 311, 312 and 313 form a brief schematic diagram of the data read-out circuit, in which 313 refers to a sense amplifier (SA), 312 refers to a read control switch Clamp, and 311 refers to an SW switch for isolating the effect of a high write operation voltage on a read operation circuit.

In the embodiments of the present disclosure, making the line resistance compensation unit resistance Rw=Rc, and taking the farthest-end redundant row as an example, there are 2ⁿ WLs following RWL<M-1:M-m>, and the 2ⁿ WLs generate the line resistance Rc; therefore, one Rc is required to additionally compensate for RWL<M-1:M-m>, and 2Rw is compensated for the other groups of RWL for every 2*2ⁿ WL intervals.

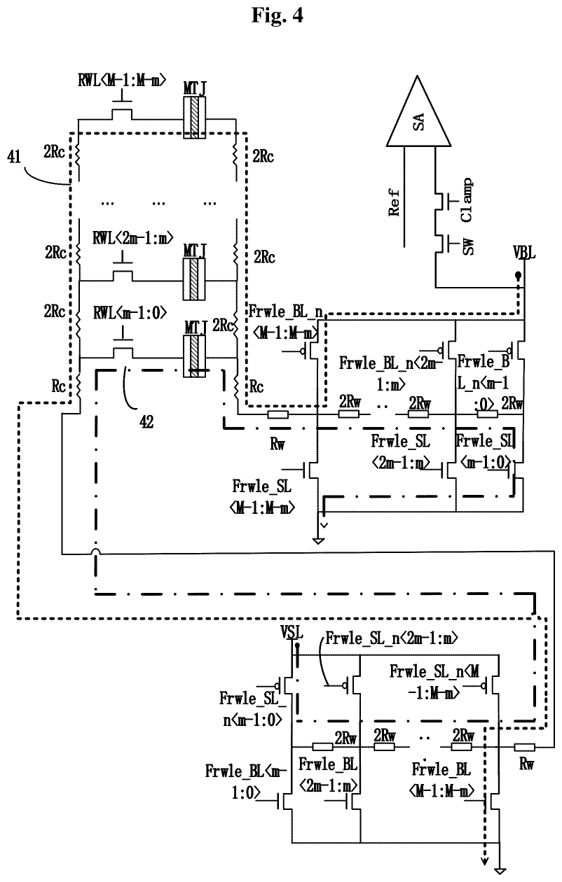

The details of the compensation scheme are described below. As shown in FIG. 4, in a case that a high voltage is applied to the VSL terminal for write-1 operation, all Frwle_BL< > signals are logically set low, and the corresponding all Frwle_BL_n< > signals are set high. Taking any RWL selected from the near-end RWL<m-1:0> as an example, since the m redundant rows in the near-end RWL<m-1:0> are adjacent, the same compensation resistor can be used. The corresponding control signal Frwle_SL<m-1:0> is high, Frwle_SL_n<m-1:0> is low, while other Frwle_SL<2m-1:m>, . . . , Frwle_SL<M-1:M-m> are low, and other Frwle_SL_n<2m-1:m>, . . . , Frwle_SL_n<M-1:M-m> are high; therefore the compensation path is the wiring 42 as shown in FIG. 4, that is, the near-end redundant row is provided with the greatest resistance compensation. Similarly, in a case that a read operation is performed or a high voltage is applied to the VBL terminal for write-0 operation, all Frwle_SL< > signals are logically set low, and the corresponding all Frwle_SL_n< > signals are set high. Taking any RWL selected from the far-end RWL<M-1:M-m> as an example, since m redundant rows in the far-end RWL<M-1:M-m> are adjacent, the same compensation resistor can be used. The corresponding control signal Frwle_BL<M-1:M-m> is high, Frwle_BL_n<M-1:M-m> is low, while other Frwle_BL<m-1:0>, Frwle_BL<2m-1:m>, . . . , etc. are low, and Frwle_BL_n<m-1:0>, Frwle_BL_n<2m-1:m>, ... are high; therefore, the compensation path is the wiring 41 as shown in FIG. 4, that is, the far-end redundant row is provided with the smallest resistance compensation.

It should be noted that, due to different structures of MTJ devices, there may be differences in write-0, write-1, and read path directions, and the read/write directions given in the embodiments are only for reference.

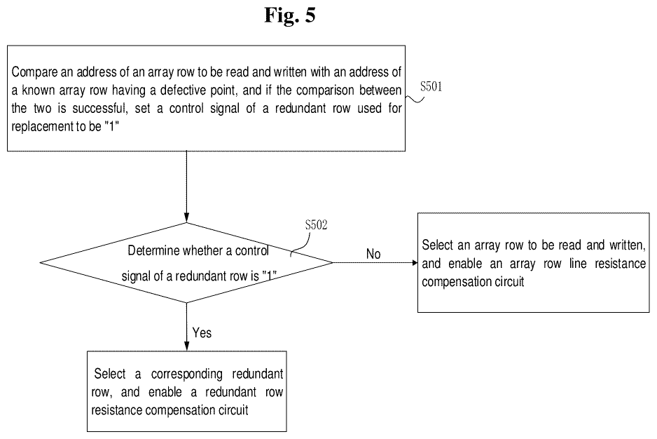

According to a second aspect, the embodiments of the present disclosure further provide a storage array read/write method. As shown in FIG. 5, the method includes:

S501, an address of an array row to be read and written is compared with an address of a known array row having a defective point, and if the comparison between the two is successful, the control signal of the redundant row for replacement is set to be “1”; and S502, it is determined whether a control signal of a redundant row is “1”, and in a case that a control signal of a redundant row is “1”, the corresponding redundant row is selected, and a redundant row line resistance compensation circuit is enabled; and in a case that all the control signals of the redundant rows are “0”, the array row to be read and written is selected, and an array row line resistance compensation circuit is enabled.

In some embodiments, the address of the known array row having a defective point is stored in a redundant address register.

The storage array read/write method provided in the embodiments of the present disclosure can effectively avoid the mismatch in line resistance compensation caused by differences in near-end and far-end positions between the redundant row and the replaced row in the existing array compensation schemes, thereby addressing issues such as reduced device lifespan or write failures. The foregoing descriptions are merely specific implementations of the present disclosure, but are not intended to limit the scope of protection of the present disclosure. Any variation or replacement readily occurred to a person skilled in the art within the technical scope disclosed in the present disclosure shall fall within the scope of protection of the present disclosure. Therefore, the scope of protection of the present disclosure shall be subject to the scope of protection of the claims.

What is claimed is:

1. A storage array read/write circuit, comprising:
a storage array, comprising a plurality of array rows and a plurality of redundant rows, wherein the array rows are used for conventional read/write data, and the redundant rows are used for replacing array rows having a defective point;
an array row line resistance compensation circuit, connected to bit lines and source lines of each column of the storage array, and configured to provide different line resistance compensation for near-end array row bit cells and far-end array row bit cells in a case that the array row bit cells perform a read/write operation, such that a line resistance of the near-end array row bit cells and a line resistance of the far-end array row bit cells is equal; and
a redundant row line resistance compensation circuit, connected to bit lines and source lines of each column of the storage array, and configured to provide different line resistance compensation for near-end redundant row bit cells and far-end redundant row bit cells in a case that the redundant row bit cells perform a read/write operation, such that a line resistance of the near-end redundant row bit cells and a line resistance of the far-end redundant row bit cells is equal.

2. The storage array read/write circuit according to claim 1, further comprising:
a determination circuit, configured to determine whether a control signal of a redundant row is “1”, and in a case that a control signal of a redundant row is “1”, select a corresponding redundant row, and enable the redundant row line resistance compensation circuit; and
in a case that all the control signals of the redundant rows are “0”, select an array row to be read and written, and enable the array row line resistance compensation circuit.

3. The storage array read/write circuit according to claim 2, further comprising:
a failure address comparison circuit, configured to compare an address of an array row to be read and written with an address of a known array row having a defective point, and if the comparison between the two is successful, set a control signal of a redundant row used for replacement to be “1”.

4. The storage array read/write circuit according to claims 1, wherein
the array rows are divided into N groups, each of which has 2*2ⁿ rows, the redundant rows are divided into N groups, each of which has m rows, and m redundant rows are inserted between every 2*2ⁿ array rows.

5. The storage array read/write circuit according to claim 4, wherein the redundant row line resistance compensation circuit comprises:
a first compensation sub-circuit connected to a bit line, comprising N first PMOSs, N first NMOSs and N compensation resistors, wherein
drain terminals of the N first PMOSs are connected together and then connected to a bit line voltage input terminal, source terminals of the N first PMOSs are connected to drain terminals of the N first NMOSs in one-to-one correspondence, source terminals of the N first NMOSs are connected together and then grounded, and the N compensation resistors are connected in series between the bit line and the drain terminals of the N first NMOSs;
the N first PMOSs are configured to respectively provide compensation paths for different redundant rows between the bit line voltage input terminal and the bit line; and
the N first NMOSs are configured to respectively provide compensation paths for different redundant rows between the bit line and the ground terminal; and
a second compensation sub-circuit connected to a source line, comprising N second PMOSs, N second NMOSs and N compensation resistors, wherein
drain terminals of the N second PMOSs are connected together and then connected to a source line voltage input terminal, source terminals of the N second PMOSs are connected to drain terminals of the N second NMOSs in one-to-one correspondence, source terminals of the N second NMOSs are connected together and then grounded, and the N compensation resistors are connected in series between the source line and the drain terminals of the N second NMOSs;
the N second PMOSs are configured to respectively provide compensation paths for different redundant rows between the source line voltage input terminal and the source line; and
the N second NMOSs are configured to respectively provide compensation paths for different redundant rows between the source line and the ground terminal.

6. The storage array read/write circuit according to claim 5, wherein gate terminals of the N first PMOSs access first control signals corresponding to the N groups of redundant rows;
gate terminals of the N first NMOSs access second control signals corresponding to the N groups of redundant rows;
gate terminals of the N second PMOSs access third control signals corresponding to the N groups of redundant rows; and
gate terminals of the N second NMOSs access fourth control signals corresponding to the N groups of redundant rows.

7. The storage array read/write circuit according to claim 5, wherein a value of a compensation resistor connected to the bit line and the drain terminals of the first NMOSs is Rw;
a value of a compensation resistor connected between the drain terminals of the first NMOSs is 2Rw;
a value of a compensation resistor connected to the source line and the drain terminals of the second NMOSs is Rw;
a value of a compensation resistor connected between the drain terminals of the second NMOSs is 2Rw;
wherein the value of Rw is equal to a parasitic line resistance of the bit line/source line wiring with the length of the 2ⁿ array rows.

8. The storage array read/write circuit according to claim 1, further comprising:
a data read-out circuit, which is connected to the bit line voltage input terminal and reads out data of array row bit cells or redundant row bit cells during a read operation.

9. A storage array read/write method, comprising:
comparing an address of an array row to be read and written with an address of a known array row having a defective point, and if the comparison between the two is successful, setting a control signal of a redundant row used for replacement to be “1”; and
determining whether a control signal of a redundant row is “1”, and in a case that a control signal of a redundant row is “1”, selecting a corresponding redundant row, and enabling a redundant row resistance compensation circuit; and in a case that all control signals of the redundant rows are “0”, selecting an array row to be read and written, and enabling an array row line resistance compensation circuit.

10. The storage array read/write method according to claim 9, wherein the address of the known array row having a defective point is stored in a redundant address register.

11. The storage array read/write circuit according to claim 3, further comprising:
input signals of the failure address comparison circuit are the address of the array row to be read and written and the address of the replaced row stored in the redundant address register, if the comparison between the two is successful, it indicates that the array row to be read and written is an array row having a defective point, and needs to be replaced with a redundant row, and the control signal of the corresponding redundant row is set to be 1; and if the comparison between the addresses is unsuccessful, it indicates that the array row to be read and written is a normal array row, and no repair and replacement is required.

12. The storage array read/write circuit according to claim 6, wherein the gate terminals of the N first PMOSs access the first control signals Frwle_BL_n<m-1:0>, Frwle_BL_n<2m-1:m>, . . . , Frwle_BL_n<M-1:M-m> corresponding to the N groups of redundant rows;
the gate terminals of the N first NMOSs access the second control signals Frwle_SL<m-1:0>, Frwle_SL<2m-1:m>, . . . , Frwle_SL<M-1:M-m> corresponding to the N groups of redundant rows;
the gate terminals of the N second PMOSs access the third control signals Frwle_SL_n<m-1:0>, Frwle_SL_n<2m-1:m>, . . . , Frwle_SL_n<M-1:M-m> corresponding to the N groups of redundant rows; and
the gate terminals of the N second NMOSs access the fourth control signals Frwle_BL<m-1:0>, Frwle_BL<2m-1:m>, . . . , Frwle_BL<M-1:M-m> corresponding to the N groups of redundant rows.

13. The storage array read/write circuit according to claim 12, wherein Frwle_SL_n< >is inverted to Frwle_SL< >, and the signal Frwle_BL_n< > is inverted to Frwle_BL< >.

14. The storage array read/write circuit according to claim 12, wherein if any RWL is selected from the near-end RWL<m-1:0>, m redundant rows in the near-end RWL<m-1:0>are adjacent, and the same compensation resistor is used, the corresponding control signal Frwle_SL<m-1:0>is high, and Frwle_SL_n<m-1:0> is low, while other Frwle_SL<2m-1: m>, . . . , Frwle_SL<M-1:M-m> are low, and other Frwle_SL_n<2m-1:m>, . . . , Frwle_SL_n<M-1:M-m> are high.

15. The storage array read/write circuit according to claim 12, wherein if taking any RWL selected from the far-end RWL<M-1:M-m>as an example, since m redundant rows in the far-end RWL<M-1:M-m>are adjacent, and the same compensation resistor is used, the corresponding control signal Frwle_BL<M-1:M-m> is high, and Frwle_BL_n<M-1:M-m> is low, while other Frwle_BL<m-1:0>, Frwle_BL<2m-1:m>, . . . , etc. are low, and Frwle_BL_n<m-1:0>, Frwle_BL_n<2m-1:m>, . . . , etc. are high.

16. The storage array read/write circuit according to claim 7, wherein
making the line resistance compensation unit resistance Rw=Rc, the farthest-end redundant row RWL<M-1:M-m> is followed by 2ⁿ array rows, which generate the line resistance Rc, one Rc is required to additionally compensate for the farthest-end redundant row RWL<M-1: M-m>, and 2Rw is compensated for the other groups of redundant rows RWL for every 2*2ⁿ WL intervals.

17. The storage array read/write circuit according to claim 8, wherein the data read-out circuit comprises a sense amplifier, a read control switch and an SW switch which are electrically connected to each other, and the SW switch is configured to isolate an effect of a high write operation voltage on a read operation circuit.

18. The storage array read/write circuit according to claim 1, wherein the array row bit cell consists of an MTJ and a CMOS.

19. The storage array read/write method according to claim 9, wherein the correlation between the redundant rows and the replaced rows is pre-configured.

20. The storage array read/write method according to claim 9, wherein in one read/write operation, only one of the redundant rows has a control signal of “1”.
